(19) United States
(12) Patent Application Publication
(10) Pub. No.: US 2024/0321697 A1
(43) Pub. Date: Sep. 26, 2024

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Toru SHONO, Himeji Hyogo (JP); Naoya NISHIJIMA, Ibo Hyogo (JP); Koji ONISHI, Ibo Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/596,794

(22) Filed: Mar. 6, 2024

(30) Foreign Application Priority Data
Mar. 24, 2023 (JP) 2023-048323

(51) Int. Cl. H01L 23/495; H01L 23/00; H01L 29/78

(52) U.S. Cl. CPC H01L 23/49562; H01L 23/49513; H01L 24/32; H01L 24/83; H01L 29/7813; H01L 2224/32245; H01L 2224/83385

(57) ABSTRACT

An embodiment includes a semiconductor portion, a first electrode, a second electrode, a first control electrode, a second control electrode, a conductive plate, and a bonding material. The first electrode, the second electrode, the first control electrode, and the second control electrode are provided above the semiconductor portion. The conductive plate is provided below the semiconductor portion. The bonding material is provided between the semiconductor portion and the conductive plate. A thin portion is thinner than a mounting portion. In a plan view, the semiconductor portion and the conductive plate are rectangular, and the conductive plate includes the mounting portion on which the semiconductor portion is mounted and the thin portion surrounding the mounting portion. Vertices of the semiconductor portion are located in the thin portion.

### CROSS-REFERENCE TO RELATED APPLICATIONS

This application is based upon and claims the benefit of priority from Japanese Patent Application No. 2023-048323, filed on Mar. 24, 2023; the entire contents of which are incorporated herein by reference.

### FIELD

Embodiments relate to a semiconductor device.

### BACKGROUND

A semiconductor device is known in which two transistors including electrically isolated source electrodes are formed on one common semiconductor substrate, and the semiconductor substrate serves as drain electrodes of the two transistors.

### DESCRIPTION OF THE DRAWINGS

FIG. 1 is a schematic plan view illustrating a semiconductor device according to a first embodiment;

FIG. 2 is a schematic side view illustrating the semiconductor device according to the first embodiment;

FIG. 3 is a schematic cross-sectional view taken along a line III-III in FIG. 1;

FIG. 4 is a schematic side view illustrating a part of the semiconductor device according to the first embodiment;

FIGS. 5 and 6 are schematic side views illustrating a part of a semiconductor device according to a comparative example.

FIG. 7 is a schematic side view illustrating a part of the semiconductor device according to the first embodiment;

FIG. 8 is a schematic plan view illustrating a semiconductor device according to a variation of the first embodiment;

FIG. 9 is a schematic plan view illustrating a semiconductor device according to another variation of the first embodiment;

FIG. 10 is a schematic plan view illustrating a semiconductor device according to a second embodiment;

FIG. 11 is a schematic perspective view illustrating a conductive member that is a part of the semiconductor device according to the second embodiment;

FIGS. 12 and 13 are schematic views illustrating a part of the semiconductor device according to the second embodiment;

FIG. 14 is a schematic plan view illustrating a semiconductor device according to a variation of the second embodiment;

FIG. 15 is a schematic perspective view illustrating a part of the semiconductor device according to the variation of the second embodiment;

FIG. 16 is a schematic plan view illustrating a semiconductor device according to another variation of the second embodiment; and

FIG. 17 is a schematic perspective view illustrating a part of the semiconductor device according to the other variation of the second embodiment.

### DETAILED DESCRIPTION

A semiconductor device according to an embodiment includes: a semiconductor portion having a first surface and a second surface located on an opposite side from the first surface, the semiconductor portion including a first region provided between the first surface and the second surface, a second region provided between the first surface and the second surface, and a semiconductor substrate connecting the first region and the second region; a first electrode provided on the first surface in the first region; a second electrode provided on the first surface in the second region and spaced apart from the first electrode; a first control electrode provided in the first region and configured to control a current flowing between the first electrode and the semiconductor substrate; a second control electrode provided in the second region and configured to control a current flowing between the second electrode and the semiconductor substrate; a conductive plate having a third surface facing the second surface and a fourth surface located on an opposite side from the third surface, the conductive plate being electrically connected to the semiconductor substrate via the third surface; and a bonding material having conductivity and provided between the semiconductor substrate and the conductive plate. The conductive plate includes a mounting portion provided between the third surface and the fourth surface, and a thin portion having a fifth surface located on an opposite side from the fourth surface and having a thickness between the fifth surface and the fourth surface that is smaller than a thickness of the mounting portion. The bonding material is provided between the second surface and the third surface and between the second surface and the fifth surface. In a plan view, a shape of an outer periphery of the conductive plate and a shape of an outer periphery of the semiconductor portion are each rectangular, four first vertices of the conductive plate are disposed corresponding to four second vertices of the semiconductor portion respectively, the outer periphery of the conductive plate coincides with the outer periphery of the semiconductor portion or is located outside the outer periphery of the semiconductor portion, and at least one of the four second vertices is located within a region of the thin portion.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

### First Embodiment

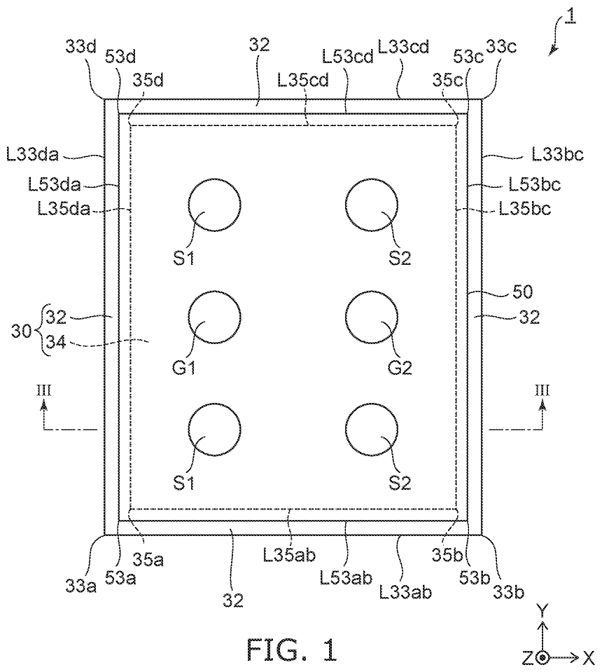

FIG. 1 is a schematic plan view illustrating a semiconductor device according to a first embodiment.

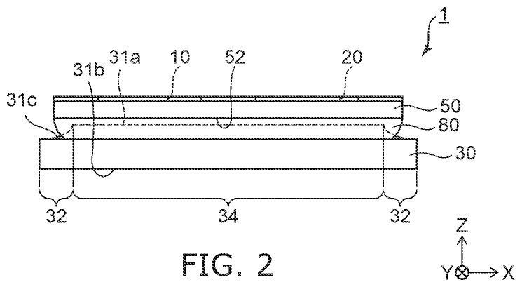

FIG. 2 is a schematic side view illustrating the semiconductor device according to the first embodiment.

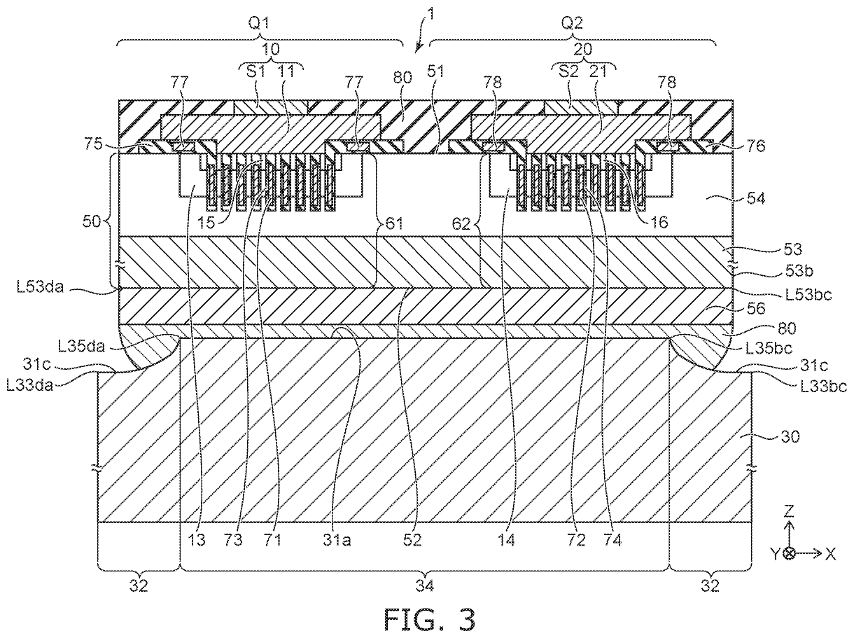

FIG. 3 is a schematic cross-sectional view taken along a line III-III in FIG. 1.

As shown in FIGS. 1 to 3, a semiconductor device 1 according to the embodiment includes a semiconductor portion 50, a first electrode 10, a second electrode 20, first control electrodes 71, second control electrodes 72, a conductive member (conductive plate) 30, and a joining member (bonding material) 80. The first electrode 10 is electrically connected to a first source electrode pad S1. The second electrode 20 is electrically connected to a second source electrode pad S2. Each of the first electrode 10 and the second electrode 20 functions as a source electrode. The first control electrode 71 is electrically connected to a first gate electrode pad G1. The second control electrode 72 is electrically connected to a second gate electrode pad G2. The first control electrode 71 and the second control electrode 72 function as gate electrodes.

The semiconductor portion 50 is disposed on the conductive member 30. The joining member 80 is disposed between the semiconductor portion 50 and the conductive member 30. The semiconductor portion 50 includes a first surface 51 and a second surface 52. The second surface 52 is a surface located on an opposite side from the first surface 51.

In the following description, an X-Y-Z three-dimensional coordinate system may be used. An X axis and a Y axis are orthogonal to each other. A plane including the X axis and the Y axis is parallel to the first surface 51 or the second surface 52. A Z axis is orthogonal to the X axis and the Y axis. A direction from the second surface 52 toward the first surface 51 is taken as a positive direction of the Z axis. The positive direction of the Z axis may be referred to as “above” or “upper”, and a negative direction of the Z axis may be referred to as “below” or “lower”, but these names do not indicate a direction of gravity. A view from “above” and a view from “below” may be referred to as plan views. A view from a direction orthogonal to an X-Y plane may be referred to as a side view.

A conductive layer 56 is provided at the second surface 52 of the semiconductor portion 50. The conductive layer 56 is ohmic-connected to the semiconductor portion 50. The semiconductor portion 50 is electrically connected to the conductive member 30 via the conductive layer 56 and the joining member 80 having conductivity.

The conductive layer 56 is electrically connected to a semiconductor substrate 53. As described later with reference to FIG. 3, the semiconductor device 1 includes a first transistor Q1 and a second transistor Q2, and the first transistor Q1 and the second transistor Q2 are electrically connected to each other by the common semiconductor substrate 53, the common conductive layer 56, the common joining member 80, and the common conductive member 30. The first transistor Q1 and the second transistor Q2 include the electrically isolated first electrode 10 and second electrode 20. When the first transistor Q1 and the second transistor Q2 are turned on, the first electrode 10 and the second electrode 20 are electrically connected via the semiconductor substrate 53, the conductive layer 56, the joining member 80, and the conductive member 30. That is, the first transistor Q1 and the second transistor Q2 form a bidirectional switch.

In the semiconductor portion 50, the semiconductor substrate 53 corresponds to a common drain electrode of the first transistor Q1 and the second transistor Q2. The semiconductor substrate 53, which is the common drain electrode of the first transistor Q1 and the second transistor Q2, is stacked above the conductive layer 56, the joining member 80, and the conductive member 30.

The conductive member 30 is formed of a metal or the like having a high conductivity. A length of the conductive member 30 in a Z-axis direction, that is, a thickness of the conductive member 30 is sufficiently large. For example, the thickness of the conductive member 30 ranges from appropriately the same as to appropriately seven times a thickness of the semiconductor portion 50, and is appropriately 0.05 mm to 0.3 mm. The conductivity of the conductive member 30 is sufficiently higher than those of a first semiconductor layer 54, the semiconductor substrate 53, the conductive layer 56, and the joining member 80. By connecting the conductive member 30 in parallel to the common drain electrode of the first transistor Q1 and the second transistor Q2, the semiconductor device 1 functions as a bidirectional switch having a low on-resistance.

A configuration of the conductive member 30 will be described.

As shown in FIG. 1, an outer periphery of the conductive member 30 has a rectangular shape including four vertices (first vertices) 33a to 33d in the plan view. The outer periphery of the conductive member 30 has the rectangular shape defined by side portions L33ab to L33da in the plan view. The side portion L33ab is a straight line between the vertices 33a and 33b. The side portion L33bc is a straight line between the vertices 33b and 33c. The side portion L33cd is a straight line between the vertices 33c and 33d. The side portion L33da is a straight line between the vertices 33d and 33a. The conductive member 30 is such a rectangular plate-shaped member.

The conductive member 30 includes a thin portion 32 and a mounting portion 34. The thin portion 32 is continuous with the mounting portion 34 at an outer edge of the conductive member 30 and surrounds the mounting portion 34. In the plan view, a boundary between the thin portion 32 and the mounting portion 34 has a rectangular shape including four vertices 35a to 35d. The boundary between the thin portion 32 and the mounting portion 34 may be referred to as an outer periphery of the mounting portion 34. The outer periphery of the mounting portion 34 has a rectangular shape defined by side portions L35ab to L35da. The side portion L35ab is a straight line between the vertices 35a and 35b. The side portion L35bc is a straight line between the vertices 35b and 35c. The side portion L35cd is a straight line between the vertices 35c and 35d. The side portion L35da is a straight line between the vertices 35d and 35a. The mounting portion 34 is a rectangular portion surrounded by the four vertices 35a to 35d and the four side portions L35ab to L35da. The thin portion 32 is a portion between a rectangular portion surrounded by the four vertices 33a to 33d and the four side portions L33ab to L33da and the outer periphery of the mounting portion 34.

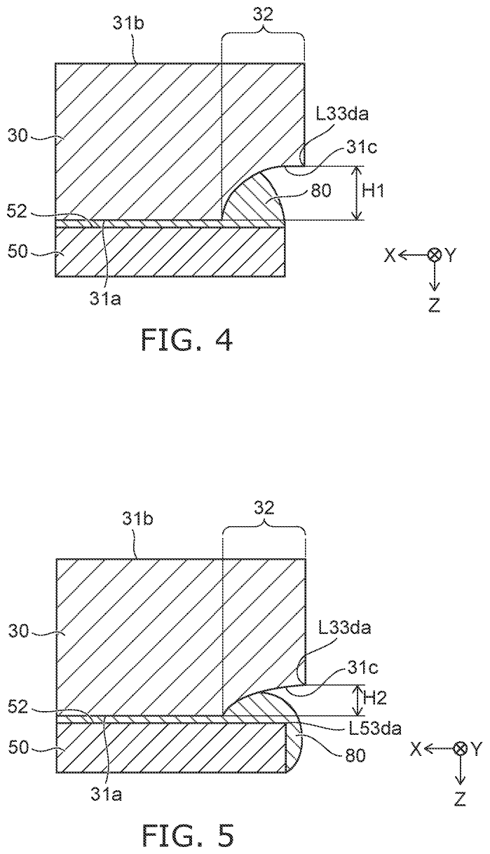

As shown in FIG. 2, the conductive member 30 includes a third surface 31a, a fourth surface 31b, and a fifth surface 31c. The third surface 31a of the conductive member 30 is a substantially flat surface over the entire surface, and faces the second surface 52 of the semiconductor portion 50. The third surface 31a is a surface of the mounting portion 34. The fourth surface 31b is a surface located on an opposite side from the third surface 31a. The fourth surface 31b is a substantially flat surface over the entire surface. The fifth surface 31c is a surface of the thin portion 32. The fifth surface 31c is a surface located on the same side as the third surface 31a and on an opposite side from the fourth surface 31b. In FIG. 2, the conductive layer 56 is not shown to avoid complication of the drawing. In FIGS. 4 to 7, 12, and 13, the conductive layer 56 is not shown either.

A thickness of the mounting portion 34 is substantially constant over the entire mounting portion 34. A thickness of the thin portion 32 is smaller than that of the mounting portion 34. The thickness of the thin portion 32 is a length from the fifth surface 31c to the fourth surface 31b along the Z-axis direction. The thickness of the mounting portion 34 is a length from the third surface 31a to the fourth surface 31b along the Z-axis direction. In a specific example in FIG. 2, the thin portion 32 has the same thickness as that of the mounting portion 34 at the boundary between the thin portion 32 and the mounting portion 34, and becomes thinner from the boundary toward an outer edge of the thin portion 32. The fifth surface 31c, which is the surface of the thin portion 32, is a concave curved surface, and in a side view, the fifth surface 31c is a part of an arc of a circle or an ellipse centered on a fifth surface 31c side.

A shape of the thin portion is not limited to the example, and may be another shape. For example, the thickness of the thin portion may be reduced linearly from the boundary between the thin portion and the mounting portion. Alternatively, the thickness of the thin portion may be reduced stepwise from the boundary between the thin portion and the mounting portion.

The semiconductor portion 50 is a rectangular plate-shaped member including vertices (second vertices) 53a to 53d in the plan view. An outer periphery of the semiconductor portion 50 in the plan view has a rectangular shape defined by side portions L53ab to L53da. The side portion L53ab is a straight line between the vertices 53a and 53b. The side portion L53bc is a straight line between the vertices 53b and 53c. The side portion L53cd is a straight line between the vertices 53c and 53d. The side portion L53da is a straight line between the vertices 53d and 53a.

In the plan view, the semiconductor portion 50 is disposed such that the outer periphery of the semiconductor portion 50 is located between the outer periphery of the mounting portion 34 and an outer periphery of the thin portion 32. That is, the vertices 53a to 53d of the semiconductor portion 50 are respectively located between the vertices 35a to 35d of the mounting portion 34 and the vertices 33a to 33d of the thin portion 32. The side portions L53ab to L53da of the semiconductor portion 50 are respectively located between the side portions L35ab to L35da of the mounting portion 34 and the side portions L33ab to L33da of the thin portion 32. From a viewpoint of equalizing a stress generated when a thermal stress is applied to the semiconductor device 1, the side portions L53ab to L53da of the semiconductor portion 50 are favorably located substantially parallel to the side portions L33ab to L33da of the thin portion 32, respectively, and substantially parallel to the side portions L35ab to L35da of the mounting portion 34, respectively.

The joining member 80 is provided between the second surface 52 of the semiconductor portion 50 and the third surface 31a of the conductive member 30. The joining member 80 is also provided between the second surface 52 of the semiconductor portion 50 and the fifth surface 31c of the conductive member 30.

In the conductive member 30, the length in the Z-axis direction from the third surface 31a to the fifth surface 31c is smaller than the length in the Z-axis direction from the third surface 31a to the fourth surface 31b. Therefore, a thickness of the joining member 80 between the second surface 52 and the fifth surface 31c is larger than a thickness of the joining member 80 between the second surface 52 and the third surface 31a.

The joining member 80 is, for example, solder, a conductive adhesive, or a conductive paste. The conductive member 30 is formed of, for example, an alloy containing Cu, Al, or the like. The semiconductor portion 50 is formed of Si or the like. Linear expansion coefficients of the joining member 80 and the conductive member 30 are larger than that of the semiconductor portion 50. Therefore, when the thermal stress is applied to the semiconductor device 1 including the above components, the stress is concentrated on the semiconductor portion 50 due to a difference in linear expansion between the semiconductor portion 50, the joining member 80 and the conductive member 30. The stress due to the thermal stress may concentrate on an outer edge of the semiconductor portion 50, and may concentrate more on corner portions including the vertices 53a to 53d of the semiconductor portion 50.

An elastic modulus of the joining member 80 is smaller than those of the conductive member 30 and the semiconductor portion 50. That is, the joining member 80 is softer than the conductive member 30 and the semiconductor portion 50. Therefore, even when the thermal stress is applied to the semiconductor device 1 and the conductive member 30 is deformed according to the linear expansion coefficient, the joining member 80 can relax the deformation and relax stress concentration on the semiconductor portion 50. In the semiconductor device 1 according to the embodiment, since the thin portion 32 of the conductive member 30 is formed in the vicinity of the outer edge of the semiconductor portion 50 such that the thickness of the joining member 80 is increased, the stress concentration due to the thermal stress can be relaxed over the entire semiconductor portion 50.

On the other hand, the thickness of the joining member 80 is sufficiently small between the mounting portion 34 of the conductive member 30 and the semiconductor portion 50. When a conductivity of the joining member 80 is lower than that of the conductive member 30, by reducing the thickness of the joining member 80 at the mounting portion 34, an electrical resistance between the semiconductor portion 50 and the conductive member 30 can be reduced, and an on-resistance of the semiconductor device 1 can be further reduced. Since the joining member 80 is sufficiently thin between the mounting portion 34 and the semiconductor portion 50, a thermal resistance is reduced, heat generation in the semiconductor device 1 is prevented, and an increase in the on-resistance due to a temperature rise can be prevented.

FIG. 4 is a schematic side view illustrating a part of the semiconductor device according to the embodiment.

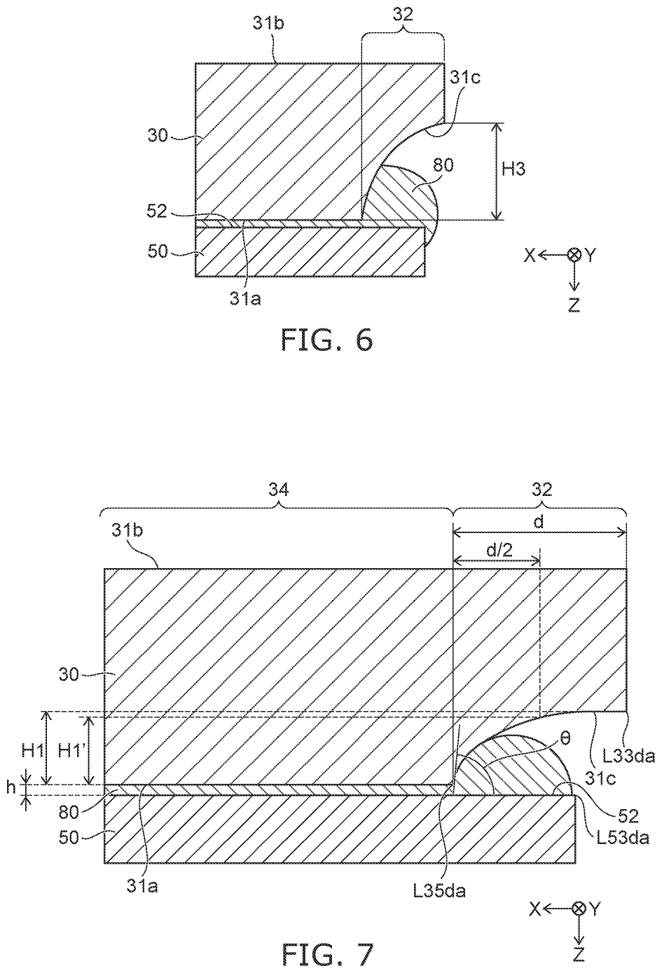

FIGS. 5 and 6 are schematic side views illustrating a part of a semiconductor device according to a comparative example.

FIGS. 4 to 6 show a relationship between a depth of the thin portion 32 of the conductive member 30 and the thickness of the joining member 80 in the semiconductor device 1 according to the embodiment.

In FIGS. 4 to 6, H1 to H3 represent depths of the thin portion 32. The depth of the thin portion 32 is a length in a direction parallel to the Z axis, which is obtained by subtracting a length from the side portion L33da to the fourth surface 31b from a length from the third surface 31a to the fourth surface 31b.

FIG. 4 shows an example in which the depth H1 of the thin portion 32 is appropriate.

FIG. 5 shows an example in which the depth H2 of the thin portion 32 is excessively small.

FIG. 6 shows an example in which the depth H3 of the thin portion 32 is excessively large.

As shown in FIGS. 4 to 6, a relationship among the depths H1 to H3 is H2<H1<H3. In each case in FIGS. 4 to 6, a volume of the joining member 80 introduced into the thin portion 32 is the same.

As shown in FIG. 4, when the depth H1 of the thin portion 32 is appropriate, the thickness of the joining member 80 introduced into the thin portion 32 is substantially equal to the depth H1. The joining member 80 does not protrude from a position of the side portion L53da of the semiconductor portion 50.

As shown in FIG. 5, when the depth H2 of the thin portion 32 is excessively small, the thickness of the joining member 80 introduced into the thin portion 32 is substantially equal to the depth H2. On the other hand, the joining member 80 may reach a side surface of the semiconductor portion 50 as a result of protruding beyond the side portion L53da of the semiconductor portion 50. When the depth H2 is even smaller, the joining member 80 introduced into the thin portion 32 may creep up from the side surface to an upper surface of the semiconductor portion 50. Electrodes or the like having different potentials may be formed on the side surface or the upper surface of the semiconductor portion 50, and the protruding joining member 80 may cause a short-circuit failure or the like in the semiconductor device 1.

As shown in FIG. 6, when the depth H3 of the thin portion 32 is excessively large, the thickness of the joining member 80 introduced into the thin portion 32 is smaller than the depth H3. Therefore, a relaxation effect of the joining member 80 on the stress concentration due to expansion and contraction of the conductive member 30 due to the thermal stress is reduced. In a case where the joining member 80 is solder or the like, when a contact area between the joining member 80 and the fifth surface 31c is reduced, a wetting area is also reduced, and thus the joining member 80 may flow to the side surface of the semiconductor portion 50, which may cause a short-circuit failure or the like in the semiconductor device 1 similarly to the example shown in FIG. 5.

As described above, the thin portion 32 may have an appropriate depth.

FIG. 7 is a schematic side view illustrating a part of the semiconductor device according to the first embodiment.

FIG. 7 shows an example for setting the appropriate depth H1 of the thin portion 32. In the semiconductor device 1 according to the embodiment, in order to set the appropriate depth H1 of the thin portion 32, the following mutual relationship between a shape of the conductive member 30 and a shape of the semiconductor portion 50 is favorably satisfied. That is, the mutual relationship between the shape of the conductive member 30 and the shape of the semiconductor portion 50 is that the thickness of the conductive member 30 is appropriately one to seven times the thickness of the semiconductor portion 50, and the thickness of the conductive member 30 is appropriately 0.05 to 0.30 mm. The position of the side portion L53da of the semiconductor portion 50 ranges from appropriately the same as to appropriately 0.1 mm inside a position of the side portion L33da of the conductive member 30.

A length d is a length from a position of the side portion L35da on the X axis to the position of the side portion L33da on the X axis, and is a length of the thin portion 32 in an X-axis direction. A length d/2 is half the length from the position of the side portion L35da on the X axis to the position of the side portion L33da on the X axis. In the example, the thickness of the thin portion 32 decreases toward the outer edge, and a depth H1′ at d/2 is smaller than the depth H1 at d.

θ indicates an angle with respect to the second surface 52 at a boundary between the mounting portion 34 and the thin portion 32, that is, the side portion L35da. When the joining member 80 is solder or the like, an angle at which the joining member 80 is sufficiently wet on the fifth surface 31c is set such that the joining member 80 of a sufficient volume is introduced into the thin portion 32. When a wettability contact angle θL of the joining member 80 is defined, the angle θ favorably satisfies the following Equation (1).

$$θ = θ L \pm 10 \% \qquad ( 1 )$$

When the joining member 80 is solder or the like, H1 favorably satisfies the following Equation (2) in addition to Equation (1).

$$H 1 = 5 h \pm 3 h \qquad ( 2 )$$

Here, h is a thickness of the joining member 80 at the mounting portion 34. The thickness of the joining member 80 is a length from the second surface 52 to the third surface 31a along the Z-axis direction. As in the example, in a case of H1′<H1, H1′ favorably satisfies Equation (2) when H1 in Equation (2) is replaced with H1′.

At least one of Equation (1) and Equation (2) is favorably satisfied, and both of Equation (1) and Equation (2) are preferably satisfied. The joining member 80 of an appropriate thickness can be provided in the thin portion 32 by satisfying relationships of Equation (1) and Equation (2).

Examples when viewed from a direction of the side portion L33da have been described with reference to FIGS. 4 to 7, and similarly, when viewed from other side portions, the joining member 80 of an appropriate thickness can also be provided in the thin portion 32 by satisfying the relationships of Equation (1) and Equation (2).

Next, configurations of the first transistor Q1 and the second transistor Q2 will be described. Returning to FIG. 3, the description will be continued.

As shown in FIG. 3, the semiconductor portion 50 includes the semiconductor substrate 53, the first semiconductor layer 54 provided on the semiconductor substrate 53, a second semiconductor layer 13 and a third semiconductor layer 14 provided in the first semiconductor layer 54, a fourth semiconductor layer 15 provided in the second semiconductor layer 13, and a fifth semiconductor layer 16 provided in the third semiconductor layer 14.

The semiconductor substrate 53 is, for example, an n-type silicon substrate. The first semiconductor layer 54 is, for example, an n-type silicon layer. An n-type impurity concentration of the first semiconductor layer 54 is lower than an n-type impurity concentration of the semiconductor substrate 53. The first semiconductor layer 54 is epitaxially grown on the semiconductor substrate 53, for example.

The second semiconductor layer 13 and the third semiconductor layer 14 are, for example, p-type silicon layers. The first semiconductor layer 54 is in contact with a bottom surface and a side surface of the second semiconductor layer 13 and a bottom surface and a side surface of the third semiconductor layer 14.

The fourth semiconductor layer 15 and the fifth semiconductor layer 16 are, for example, n-type silicon layers. In addition, n-type impurity concentrations of the fourth semiconductor layer 15 and the fifth semiconductor layer 16 are higher than the n-type impurity concentration of the first semiconductor layer 54. The second semiconductor layer 13 is in contact with a bottom surface and a side surface of the fourth semiconductor layer 15. The third semiconductor layer 14 is in contact with a bottom surface and a side surface of the fifth semiconductor layer 16.

A surface of the first semiconductor layer 54, a surface of the second semiconductor layer 13, a surface of the third semiconductor layer 14, a surface of the fourth semiconductor layer 15, and a surface of the fifth semiconductor layer 16 constitute the first surface 51 of the semiconductor portion 50. A back surface of the semiconductor substrate 53 constitutes the second surface 52 of the semiconductor portion 50.

The semiconductor portion 50 includes a first region 61 and a second region 62 between the first surface 51 and the second surface 52. The first region 61 and the second region 62 are arranged along the X-axis direction in the semiconductor portion 50.

The semiconductor substrate 53 and the first semiconductor layer 54 are provided in common to the first region 61 and the second region 62. The second semiconductor layer 13 and the fourth semiconductor layer 15 are provided in the first region 61. The third semiconductor layer 14 and the fifth semiconductor layer 16 are provided in the second region 62.

Multiple first control electrodes 71 that are gate electrodes are provided in the first region 61. The first control electrode 71 is, for example, a trench gate and extends in the first region 61 along the Z-axis direction. An upper surface, a side surface, and a bottom surface of the first control electrode 71 are covered with an insulating film 73. The side surface of the first control electrode 71 faces the second semiconductor layer 13 via the insulating film 73.

Multiple second control electrodes 72 that are gate electrodes are provided in the second region 62. The second control electrode 72 is, for example, a trench gate and extends in the second region 62 along the Z-axis direction. An upper surface, a side surface, and a bottom surface of the second control electrode 72 are covered with an insulating film 74. The side surface of the second control electrode 72 faces the third semiconductor layer 14 via the insulating film 74.

For example, the multiple first control electrodes 71 are spaced apart in the X-axis direction, and each of the multiple first control electrodes 71 extends in a Y-axis direction. The multiple second control electrodes 72 are spaced apart in the X-axis direction, and each of the multiple second control electrodes 72 extends in the Y-axis direction.

The first electrode 10 that is a source electrode is provided on the first surface 51 in the first region 61 of the semiconductor portion 50. The first electrode 10 includes a first metal portion 11 in contact with the fourth semiconductor layer 15 on the first surface 51 of the semiconductor portion 50, and the first source electrode pad S1 provided on the first metal portion 11.

An area of the first metal portion 11 is larger than an area of the first source electrode pad S1. The area of the first metal portion 11 represents an area of the first metal portion 11 in contact with the first surface 51 of the semiconductor portion 50, or an area of a surface of the first metal portion 11. The area of the first source electrode pad S1 represents an area of a surface of the first source electrode pad S1. In other words, an area of at least a part of the first metal portion 11 in the X-Y plane is larger than an area of at least a part of the first source electrode pad S1 in the X-Y plane.

The first metal portion 11 mainly contains, for example, aluminum, and functions as a contact layer that reduces a contact resistance with the semiconductor portion 50. An outermost surface of the first source electrode pad S1 includes, for example, a gold film having excellent solder wettability. For example, a nickel film is formed between the gold film and the first metal portion 11 to improve adhesion therebetween.

A first wiring layer 77 is provided on the first surface 51 in the first region 61 of the semiconductor portion 50. The first wiring layer 77 is electrically connected to the first control electrode 71. An insulating film 75 is provided between the first wiring layer 77 and the first electrode 10 and between the first wiring layer 77 and the semiconductor portion 50.

The second electrode 20 that is a source electrode is provided on the first surface 51 in the second region 62 of the semiconductor portion 50. The second electrode 20 includes a third metal portion 21 in contact with the fifth semiconductor layer 16 on the first surface 51 of the semiconductor portion 50, and the second source electrode pad S2 provided on the third metal portion 21.

An area of the third metal portion 21 is larger than an area of the second source electrode pad S2. The area of the third metal portion 21 represents an area of the third metal portion 21 in contact with the first surface 51 of the semiconductor portion 50, or an area of a surface (an upper surface in FIG. 3) of the third metal portion 21. The area of the second source electrode pad S2 represents an area of a surface (an upper surface in FIG. 3) of the second source electrode pad S2. In other words, an area of at least a part of the third metal portion 21 in the X-Y plane is larger than an area of at least a part of the second source electrode pad S2 in the X-Y plane.

The third metal portion 21 mainly contains, for example, aluminum, and functions as a contact layer that reduces a contact resistance with the semiconductor portion 50. An outermost surface of the second source electrode pad S2 includes, for example, a gold film having excellent solder wettability. For example, a nickel film is formed between the gold film and the third metal portion 21 to improve adhesion therebetween.

A second wiring layer 78 is provided on the first surface 51 in the second region 62 of the semiconductor portion 50. The second wiring layer 78 is electrically connected to the second control electrode 72. An insulating film 76 is provided between the second wiring layer 78 and the second electrode 20 and between the second wiring layer 78 and the semiconductor portion 50.

An insulating film 80 is provided on the first surface 51 of the semiconductor portion 50. The insulating film 80 covers the first metal portion 11 of the first electrode 10 and the third metal portion 21 of the second electrode 20. The insulating film 80 covers a side surface of the first source electrode pad S1 of the first electrode 10 and a side surface of the second source electrode pad S2 of the second electrode 20. The surface of the first source electrode pad S1 of the first electrode 10 and the surface of the second source electrode pad S2 of the second electrode 20 are exposed from the insulating film 80.

The conductive layer 56 is provided at the second surface 52 of the semiconductor portion 50. The conductive layer 56 is provided in common to the first region 61 and the second region 62 of the semiconductor portion 50, and electrically connects the first region 61 and the second region 62. The conductive layer 56 contains a metal having a resistivity lower than that of the semiconductor substrate 53, and a metal that is ohmic-connected to the semiconductor substrate 53 containing Si. The conductive layer 56 contains Ag, Ti, Ni, or the like.

The semiconductor device 1 includes the first transistor Q1 and the second transistor Q2 sharing the semiconductor substrate 53 with a structure described above. The first transistor Q1 and the second transistor Q2 are adjacent to each other in an X-direction. The first transistor Q1 and the second transistor Q2 are, for example, metal-oxide-semiconductor field effect transistors (MOSFETs).

The first electrode 10 functions as a source electrode of the first transistor Q1, and the fourth semiconductor layer 15 functions as a source layer electrically connected to the first electrode 10. When a predetermined voltage is applied to the first control electrode 71, a channel is formed in a portion of the second semiconductor layer 13 facing the first control electrode 71.

The second electrode 20 functions as a source electrode of the second transistor Q2, and the fifth semiconductor layer 16 functions as a source layer electrically connected to the second electrode 20. When a predetermined voltage is applied to the second control electrode 72, a channel is formed in a portion of the third semiconductor layer 14 facing the second control electrode 72.

The first electrode 10 and the second electrode 20 are spaced apart from each other and are electrically isolated from each other.

For example, two first source electrode pads S1 are provided on the first metal portion 11 of the first electrode 10. For example, two second source electrode pads S2 are provided on the third metal portion 21 of the second electrode 20.

The first gate electrode pad G1 electrically connected to the first control electrode 71 via the first wiring layer 77 and the second gate electrode pad G2 electrically connected to the second control electrode 72 via the second wiring layer 78 are provided on the first surface 51 of the semiconductor portion 50. A periphery of the first gate electrode pad G1 and a periphery of the second gate electrode pad G2 are covered with an insulating film 79, and a surface of the first gate electrode pad G1 and a surface of the second gate electrode pad G2 are exposed from the insulating film 79.

The semiconductor device 1 according to the embodiment is incorporated into a charge and discharge protection circuit for a Li-ion battery, for example, and is used as a bidirectional switch. In the semiconductor device 1 according to the embodiment, the conductive member 30 facing the second surface 52 of the semiconductor portion 50 is electrically connected to the semiconductor portion 50 via the joining member 80. Since the conductive member 30 is configured such that the conductivity of the conductive member 30 is sufficiently high, it is possible to reduce a voltage drop when a current flows bidirectionally through a series circuit of the first transistor Q1 and the second transistor Q2.

The first transistor Q1 and the second transistor Q2 each have a trench gate structure in the above description, but the invention is not limited thereto, and any other appropriate transistor structures may be used. For example, the first transistor Q1 and the second transistor Q2 may each have a planar gate structure.

Effects of the semiconductor device 1 according to the embodiment will be described.

The semiconductor device 1 according to the embodiment includes the semiconductor portion 50, the first electrode 10, the second electrode 20, the first control electrodes 71, the second control electrodes 72, the conductive member 30, and the joining member 80. As for the first transistor Q1 and the second transistor Q2, the semiconductor substrate 53 and the first semiconductor layer 54 of the semiconductor portion 50 function as a common drain electrode of the first transistor Q1 and the second transistor Q2. That is, drain electrodes of the first transistor Q1 and the second transistor Q2 are electrically connected to each other by sharing the semiconductor substrate 53 and the first semiconductor layer 54. The conductive member 30 is disposed at the second surface 52, which is a back surface of the semiconductor portion 50, via the joining member 80 having conductivity, and the conductive member 30 is electrically connected to the semiconductor substrate 53 of the semiconductor portion 50. The conductivity of the conductive member 30 is sufficiently higher than those of the semiconductor substrate 53 and the first semiconductor layer 54. Therefore, the drain electrodes of the first transistor Q1 and the second transistor Q2 are electrically connected to each other with a low resistance, and the semiconductor device 1 can be a bidirectional switch with a low on-resistance.

The conductive member 30 includes the mounting portion 34 and the thin portion 32, and the thin portion 32 is provided around the mounting portion 34. A thickness of the thin portion 32 is smaller than that of the mounting portion 34. In a plan view, outer periphery of the semiconductor portion 50 is a region of the thin portion 32. The joining member 80 is provided between the mounting portion 34 and the semiconductor portion 50, and between the thin portion 32 and the semiconductor portion 50. A thickness of the thin portion 32 is smaller than that of the mounting portion 34, and a thickness of the joining member 80 at the thin portion 32 is larger than that of the joining member 80 at the mounting portion 34. An elastic modulus of the joining member 80 is smaller than those of the semiconductor portion 50 and the conductive member 30. Therefore, when a thermal stress is applied to the semiconductor device 1, the conductive member 30 expands and contracts more than the semiconductor portion 50. Contraction of the conductive member 30 is relaxed by the joining member 80. Since a stress due to expansion and contraction of the conductive member 30 is concentrated in the vicinity of an outer edge of the semiconductor portion, stress concentration is relaxed by the joining member 80 introduced into the thin portion 32.

The thickness of the joining member 80 at the mounting portion 34 is smaller than that of the joining member 80 at the thin portion 32. Even when the conductivity of the joining member 80 is lower than that of the conductive member 30, the electrical resistance between the semiconductor portion 50 and the conductive member 30 can be sufficiently low. Even when a thermal conductivity of the joining member 80 is lower than that of the conductive member 30, a thermal resistance between the semiconductor portion 50 and the conductive member 30 can be sufficiently low.

There is known a semiconductor device in which two transistors are connected in series using a semiconductor substrate as a common drain electrode (for example, Patent Literature 1). By connecting a metal plate having a high conductivity to the semiconductor substrate in order to reduce an electrical resistance of the drain electrode, an on-resistance of the semiconductor device can be reduced.

The semiconductor device may pass through a solder bath when to be mounted on a circuit board or the like constituting an electronic device. The solder bath may have a high temperature higher than 200° C., and a large thermal stress is applied to the semiconductor device. The semiconductor device is required to pass through a reliability test such as a temperature cycle test within a storage temperature range of the semiconductor device or a temperature shock test within a predetermined temperature range.

The conductive member 30 can be formed of a material having a conductivity higher than those of the semiconductor portion 50 and the joining member 80, and making the conductive member 30 sufficiently thick is effective in achieving a sufficiently low resistance value. On the other hand, since a volume of the conductive member 30 is increased by increasing a thickness of the conductive member 30, the volume increased due to a thermal expansion coefficient is also increased, and the stress generated accordingly is also increased. In the semiconductor device 1 according to the embodiment, the thin portion 32 is provided at an outer edge of the conductive member 30, and a volume of the joining member 80 at the thin portion 32 is increased, whereby deformation of the semiconductor portion 50 due to the stress generated by an increase in volume of the conductive member 30 can be relaxed. Therefore, even in a thermal stress environment, the semiconductor device 1 according to the embodiment can relax stress concentration on the semiconductor portion 50, and can achieve both a low on-resistance and a heat-resistant environment.

### (Variation 1)

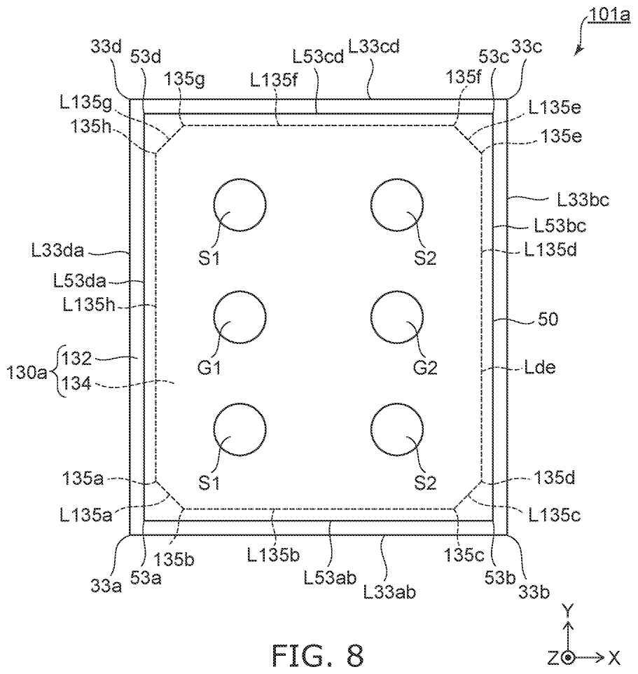

FIG. 8 is a schematic plan view illustrating a semiconductor device according to a variation of the first embodiment.

As shown in FIG. 8, a semiconductor device 101a according to the variation is different from the semiconductor device 1 shown in FIG. 1 in a configuration of a conductive member 130a. Other configurations are the same as those in the semiconductor device 1, and the same components are denoted by the same reference numerals and detailed description thereof will be omitted.

The conductive member 130a of the semiconductor device 101a includes a thin portion 132 and a mounting portion 134. The thin portion 132 is provided at an outer edge of the conductive member 130a and surrounds the mounting portion 134. In the plan view, a boundary between the thin portion 132 and the mounting portion 134 has an octagonal shape including eight vertices 135a to 135h. The boundary between the thin portion 132 and the mounting portion 134 has the octagonal shape defined by side portions L135a to L135h. Each of the side portions L135a to L135h is a straight line between two adjacent vertices. The side portions L135a, L135c, L135e, and L135g are shorter than the other side portions.

The mounting portion 134 is an octagonal portion surrounded by the eight vertices 135a to 135h and the eight side portions L135a to L135h. The thin portion 132 is a portion between the mounting portion 134 and a rectangular portion surrounded by the four vertices 33a to 33d and the four side portions L33ab to 33da.

Although not shown, a shape of the thin portion 132 in a side view becomes thinner from the boundary between the thin portion 132 and the mounting portion 134 toward an outer edge as in a case of the semiconductor device 1 shown in FIGS. 1 and 2, for example.

In the plan view, the semiconductor portion 50 is disposed such that an outer periphery of the semiconductor portion is located between an outer periphery of the mounting portion 134 and an outer periphery of the thin portion 132. In the semiconductor device 101a according to the variation, since the outer periphery of the mounting portion 134 has the octagonal shape, vertices of the semiconductor portion 50 are located farther away from side portions of the mounting portion 134 than in the case of the semiconductor device 1 shown in FIG. 1. For example, at the vertex 53a, a shortest distance between the vertex 53a and the side portion L135a is longer than a shortest distance between the side L33ab and the side L53ab. That is, in the semiconductor device 101a according to the variation, a volume of the joining member 80 can be made sufficiently larger at corner portions including the vertices of the semiconductor portion 50 than at other outer edge portions of the semiconductor portion 50.

When stress simulation is performed using a model in which a semiconductor portion and a conductive member are joined via a joining member, a stress is more concentrated on corner portions including vertices of the semiconductor portion. Therefore, in the semiconductor device 101a according to the variation, by increasing a region of the thin portion 132 including the vertices 33a to 33d of the thin portion 132, the volume of the joining member 80 covering the corner portions including the vertices of the semiconductor portion 50 is increased. Accordingly, stress concentration on the semiconductor portion 50 when a thermal stress is applied can be more effectively relaxed.

### (Variation 2)

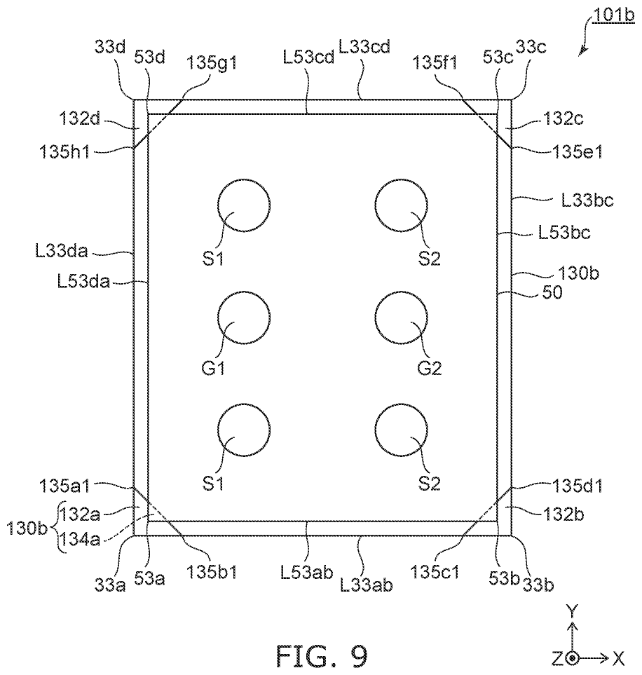

FIG. 9 is a schematic plan view illustrating a semiconductor device according to another variation of the first embodiment.

As shown in FIG. 9, a semiconductor device 101b according to the variation is different from the semiconductor device 1 shown in FIG. 1 in a configuration of a conductive member 130b. Other configurations are the same as those in the semiconductor device 1, and the same components are denoted by the same reference numerals and detailed description thereof will be omitted.

The conductive member 130b of the semiconductor device 101b includes thin portions 132a to 132d and a mounting portion 134a. An outer periphery of the thin portion 132a has a right triangular shape including vertices 33a, 135a1, and 135b1. An outer periphery of the thin portion 132b has a right triangular shape including vertices 33b, 135c1, and 135d1. An outer periphery of the thin portion 132c has a right triangular shape including vertices 33c, 135e1, and 135f1. An outer periphery of the thin portion 132d has a right triangular shape including vertices 33d, 135g1, and 135h1.

Although not shown, a shape of each of the thin portions 132a to 132d in a side view becomes thinner from a boundary between each of the thin portions 132a to 132d and the mounting portion 134a toward an outer edge as in the case of the semiconductor device 1 shown in FIGS. 1 and 2, for example.

In the plan view, the semiconductor portion 50 is disposed such that an outer periphery of the semiconductor portion is located inside an outer periphery of the conductive member 130b. In the semiconductor device 101b according to the variation, corner portions including the vertices 53a to 53d of the semiconductor portion 50 are located at the thin portions 132a to 132d, respectively. Specifically, the vertex 53a of the semiconductor portion 50 is located inside a right triangle including the vertices 33a, 135a1, and 135b1. The vertex 53b of the semiconductor portion 50 is located inside a right triangle including the vertices 33b, 135c1, and 135d1. The vertex 53c of the semiconductor portion 50 is located inside a right triangle including the vertices 33c, 135e1, and 135f1. The vertex 53d of the semiconductor portion 50 is located inside a right triangle including the vertices 33d, 135g1, and 135h1.

As described with reference to FIG. 6, when stress simulation is performed using a model in which a semiconductor portion and a conductive member are joined, a stress is more concentrated on corner portions including vertices of the semiconductor portion. Depending on a thickness and a shape of the semiconductor portion, a material of the conductive member, and the like, the stress may be hardly concentrated on side portions of the semiconductor portion 50, and may be mainly concentrated on corner portions of the semiconductor portion 50. In such a case, by applying the conductive member 130b according to the variation, stress concentration on the corner portions of the semiconductor portion 50 can be relaxed. In the variation, since the thin portions 132a to 132d are formed only at corner portions of the conductive member 130b, there is an advantage that the conductive member 130b can be easily molded.

Depending on the thickness and shape of the semiconductor portion, the material of the conductive member, and the like, the stress is not limited to being concentrated on all of the four corner portions of the semiconductor portion 50. The stress may be concentrated on a part of the four corner portions of the semiconductor portion 50 due to a misalignment or the like that may occur when the semiconductor portion 50, the joining member 80, and the conductive member 30 are joined together. Therefore, thin portions of the conductive member may be provided at positions corresponding to corner portions where the stress is concentrated based on the stress simulation or the like.

### Second Embodiment

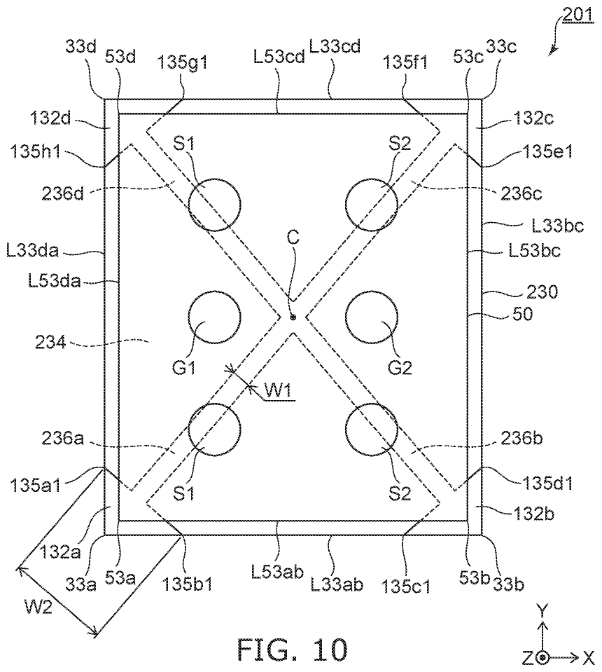

FIG. 10 is a schematic plan view illustrating a semiconductor device according to a second embodiment.

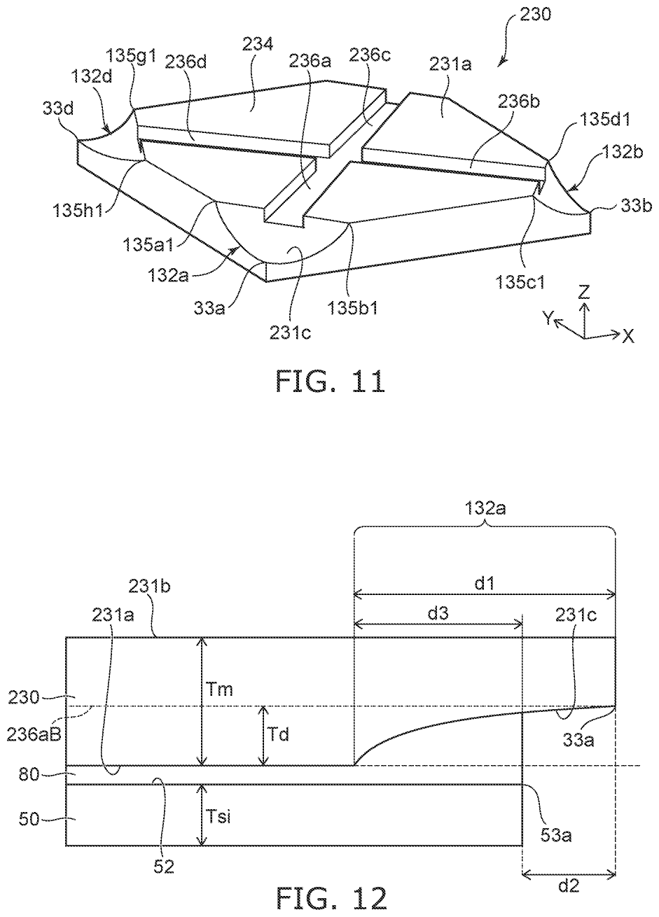

FIG. 11 is a schematic perspective view illustrating a conductive member that is a part of the semiconductor device according to the second embodiment.

As shown in FIG. 10, a semiconductor device 201 according to the embodiment is different from the semiconductor device 1 shown in FIG. 1 in a configuration of a conductive member 230. Other configurations are the same as those in the semiconductor device 1, and the same components are denoted by the same reference numerals and detailed description thereof will be omitted.

As shown in FIG. 10, the semiconductor device 201 includes the conductive member 230 instead of the conductive member 30 shown in FIG. 1. As shown in FIGS. 10 and 11, the conductive member 230 includes the thin portions 132a to 132d, a mounting portion 234, and grooves 236a to 236d. The thin portions 132a to 132d are the same as the thin portions 132a to 132d according to the variation described with reference to FIG. 9, and detailed description thereof will be omitted.

In the conductive member 230, the grooves 236a to 236d are provided in the mounting portion 234. The grooves 236a to 236d are provided on a third surface 231a side of the conductive member 230 so as to form recesses in the third surface 231a. The third surface 231a is a surface disposed at a position facing the second surface 52 of the semiconductor portion 50. The groove 236a is provided from a center C of gravity of the conductive member 230 toward the thin portion 132a. The groove 236b is provided from the center C of gravity of the conductive member 230 toward the thin portion 132b. The groove 236c is provided from the center C of gravity of the conductive member 230 toward the thin portion 132c. The groove 236d is provided from the center C of gravity of the conductive member 230 toward the thin portion 132d. The center of gravity refers to a geometric center of the member in the plan view.

A width W1 of each of the grooves 236a to 236d is favorably smaller than a width W2 of each of the thin portions 132a to 132d. The width W2 of the thin portion 132a is a length between two vertices 135a1 and 135b1 adjacent to the vertex 33a. The same applies to other thin portions 132b to 132d. In this way, the joining member 80 can be smoothly introduced into the thin portions 132a to 132d, and the joining member 80 of a sufficient volume can be formed in the thin portions 132a to 132d.

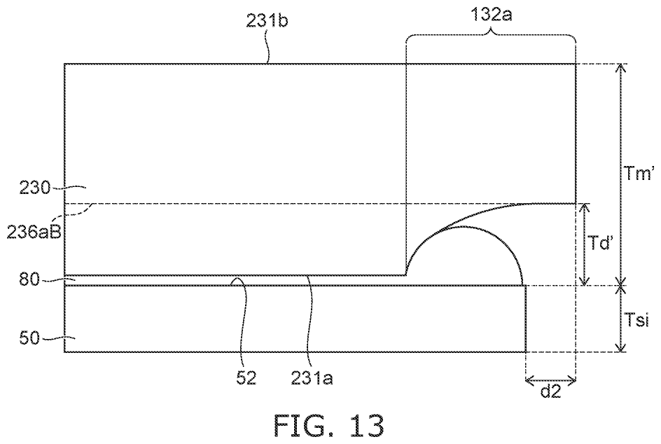

FIGS. 12 and 13 are schematic views illustrating a part of the semiconductor device according to the second embodiment.

FIG. 12 shows a mutual relationship among a depth of the thin portion 132a of the conductive member 230, a depth of the groove 236a, and a thickness of the semiconductor portion 50.

A length d1 is a smallest length from a line segment connecting the vertex 135a1 and the vertex 135b1 to the vertex 33a in FIG. 11. A length d3 is a smallest length from the line segment connecting the vertex 135a1 and the vertex 135b1 to the vertex 53a. A length d2 is a smallest length from the vertex 53a to the vertex 33a. That is, d1=d2+d3.

A thickness Tsi is a thickness of the semiconductor portion 50. A thickness Tm is a thickness of the conductive member 230. Td is a length from the third surface 231a to a bottom portion 236aB of the groove 236a in a direction along the Z axis, and represents the depth of the groove 236a.

In the semiconductor device 201 according to the embodiment, in order to relax stress concentration on corner portions of the semiconductor portion 50 including the vertex 53a of the semiconductor portion 50 when a thermal stress is applied, a mutual relationship between the shapes is favorably in an appropriate range. Specifically, the mutual relationship between the shapes is a relationship between the width W1 of the groove 236a and the width W2 of the thin portion 132a. The relationship is shown in FIG. 10. Specifically, the mutual relationship between the shapes is a position of the vertex 53a of the semiconductor portion 50 at the thin portion 132a. In FIG. 12, a relationship between d2 and d3 is shown. Another mutual relationship between the shapes is a relationship between the thickness Tm of the conductive member 230 and the depth Td of the groove 236a. Regarding the mutual relationship, the following relationship is favorably satisfied as in a case of the first embodiment. That is, the thickness Tm of the conductive member 230 is appropriately one to seven times the thickness Tsi of the semiconductor portion 50, the thickness Tm of the conductive member 230 is appropriately 0.05 mm to 0.30 mm, and d2 is appropriately 0 mm to 0.1 mm.

A first condition for relaxing the stress concentration is given by the following Equation (3).

$$W 1 \leq W 2 \qquad ( 3 )$$

By making the width W1 of the groove 236a smaller than the width W2 of the thin portion 132a, the joining member 80 of a sufficient volume can be formed in the thin portion 132a.

A second condition for relaxing the stress concentration is given by the following Equation (4).

$$d 2 < d 3 \qquad ( 4 )$$

By satisfying Equation (4), when a stress is concentrated on the corner portions including the vertices of the semiconductor portion 50, expansion and contraction of the conductive member 230 due to a thermal stress can be relaxed by the joining member 80 of the sufficient volume.

A third condition for relaxing the stress concentration is given by the following Equation (5).

$$Td = ( 1 / 10 ) \times Tm ∼ ( 1 / 1.3 ) \times Tm \qquad ( 5 )$$

When a stress is concentrated in the vicinity of the groove 236a, since the groove 236a has a sufficient depth, expansion and contraction of the conductive member 230 due to a thermal stress can be relaxed by the joining member 80 of the sufficient volume. In consideration of changes or the like in manufacturing the conductive member 230, an upper limit value of Equation (5) is provided in order to prevent the thickness of the conductive member 230 at the groove 236a from being excessively small.

All the conditions of Equation (3) to Equation (5) are favorably satisfied, but a part of the conditions may be satisfied according to a thickness and a shape of the semiconductor portion, a material of the conductive member, and the like.

FIG. 13 shows a mutual relationship among the thickness Tsi of the semiconductor portion 50, a thickness Tm′ of the conductive member 230, and a depth Td′ of the groove 236a when a depth of the groove 236a is based on the second surface 52 of the semiconductor portion 50. That is, as shown in FIG. 13, the thickness Tm′ of the conductive member 230 and the depth Td′ of the groove 236a are shown based on a thickness of the conductive member 230 including the joining member 80 between the second surface 52 and the third surface 231a.

When a thermal conductivity of the joining member 80 is lower than that of the conductive member 230, a thickness of the joining member 80 between the second surface 52 and the third surface 231a is favorably small.

All the conditions of Equation (3) to Equation (5) are favorably satisfied, but a part of the conditions may be satisfied according to a thickness and a shape of the semiconductor portion, a material of the conductive member, and the like. For example, stress simulation or the like is performed for each product to determine a portion where a stress is concentrated, and then settings are made to satisfy appropriate conditions.

Effects of the semiconductor device 201 according to the embodiment will be described.

The semiconductor device 201 according to the embodiment has the same effects as the semiconductor device 1 according to the first embodiment. In addition, the following effects are attained.

The semiconductor device 201 according to the embodiment includes the conductive member 230. The conductive member 230 includes the thin portions 132a to 132d, the mounting portion 234, and the grooves 236a to 236d. The grooves 236a to 236d are provided from the mounting portion 234 toward the thin portions 132a to 132d, respectively. By providing the grooves 236a to 236d, the joining member 80 can be sufficiently introduced into the thin portions 132a to 132d.

Regarding the grooves 236a to 236d, by appropriately satisfying Equation (3) to Equation (5) or Equations (3) and (4), the joining member 80 of the sufficient volume can be introduced into the thin portions 132a to 132d, and the stress concentration can be more effectively relaxed by disposing the grooves in portions where the stress is concentrated.

### (Variation 1)

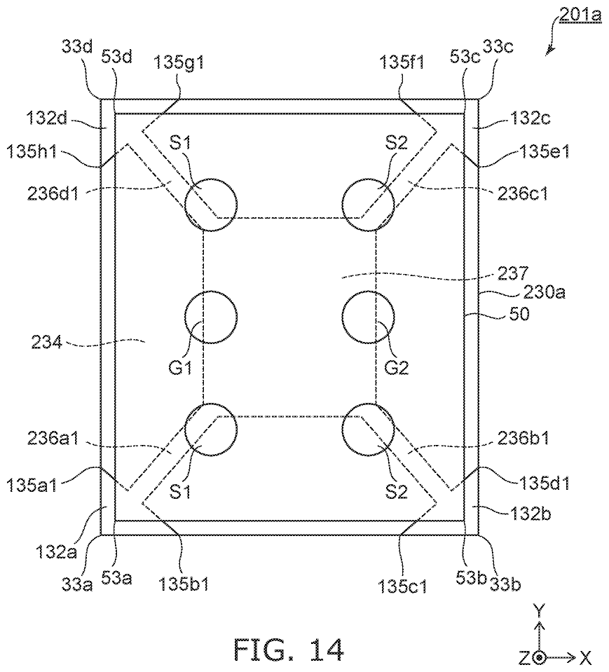

FIG. 14 is a schematic plan view illustrating a semiconductor device according to a variation of the second embodiment.

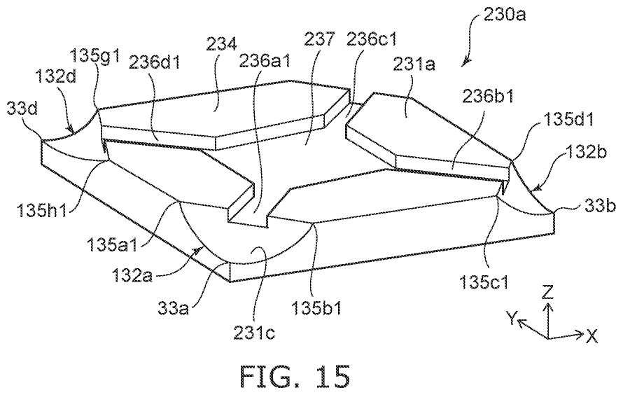

FIG. 15 is a schematic perspective view illustrating a part of the semiconductor device according to the variation of the second embodiment.

As shown in FIG. 14, a semiconductor device 201a according to the variation is different from the semiconductor device 201 shown in FIG. 10 in a configuration of a conductive member 230a. Other configurations are the same as those in the semiconductor device 201, and the same components are denoted by the same reference numerals and detailed description thereof will be omitted.

As shown in FIG. 14, the semiconductor device 201a includes the conductive member 230a instead of the conductive member 230 shown in FIG. 10. As shown in FIGS. 14 and 15, the conductive member 230a includes the thin portions 132a to 132d, the mounting portion 234, the grooves 236a to 236d, and a recess 237. The thin portions 132a to 132d, the mounting portion 234, and the grooves 236a to 236d are the same as those according to the second embodiment described with reference to FIGS. 10 and 11, and detailed description thereof will be omitted.

In the conductive member 230a, the recess 237 is provided in the mounting portion 234. The recess 237 is provided in the vicinity of a substantially central portion of the mounting portion. The grooves 236a to 236d are provided from the recess 237 toward the thin portions 132a to 132d, respectively.

The recess 237 has the same depth as those of the grooves 236a to 236d. Accordingly, depths of the recess 237 and the grooves 236a to 236d correspond to the depth Td or the depth Td′ described with reference to FIGS. 12 and 13, and are favorably set to satisfy a condition of Equation (5).

In a process of joining the conductive member 230a to the semiconductor portion 50, by providing the recess 237 in the mounting portion 234 of the conductive member 230b, the joining member 80 of a sufficient volume can be supplied between the conductive member 230a and the semiconductor portion 50. By providing the joining member 80 of the sufficient volume in a wider region between the conductive member 230a and the semiconductor portion 50, an effect of relaxing stress concentration in a wider range can be attained.

A shape of the recess 237 in the plan view is not limited to the specific example in FIGS. 14 and 15 and can be appropriately set as desired according to a thickness and a shape of the semiconductor portion, a material of the conductive member, and the like.

### (Variation 2)

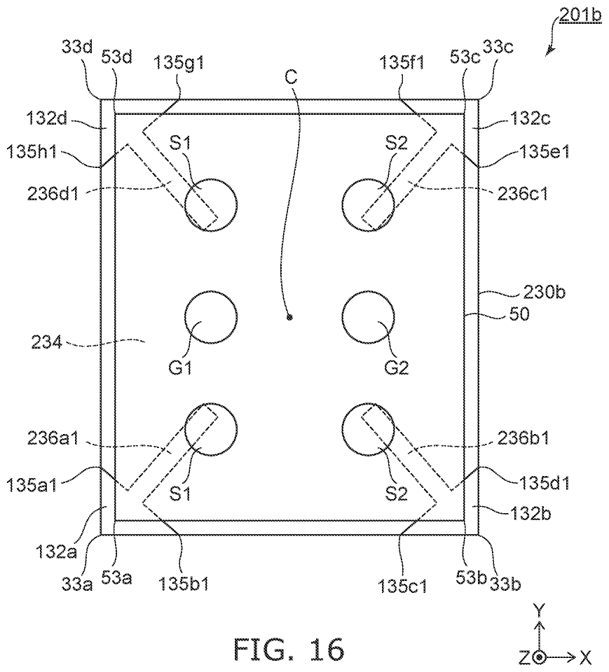

FIG. 16 is a schematic plan view illustrating a semiconductor device according to another variation of the second embodiment.

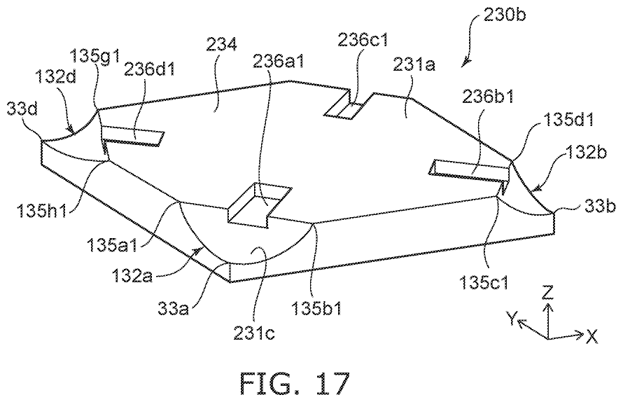

FIG. 17 is a schematic perspective view illustrating a part of the semiconductor device according to the other variation of the second embodiment.

As shown in FIG. 16, a semiconductor device 201b according to the variation is different from the semiconductor device 201 shown in FIG. 10 in a configuration of a conductive member 230b. Other configurations are the same as those in the semiconductor device 201, and the same components are denoted by the same reference numerals and detailed description thereof will be omitted.

As shown in FIG. 16, the semiconductor device 201b includes the conductive member 230b instead of the conductive member 230 shown in FIG. 10. As shown in FIGS. 16 and 17, the conductive member 230b includes the thin portions 132a to 132d, the mounting portion 234, and grooves 236a1 to 236d1. The thin portions 132a to 132d and the mounting portion 134 are the same as those according to the second embodiment described with reference to FIGS. 10 and 11, and detailed description thereof will be omitted.

In the variation, different from the grooves 236a to 236d of the conductive member 230 described with reference to FIGS. 10 and 11, the grooves 236a1 to 236d1 of the conductive member 230b are not connected but separated from one another at the center C of gravity which is a central portion of the mounting portion 234. Each of the grooves 236a1 to 236d1 extends from a position away from the center C of gravity of the mounting portion 234 to the thin portions 132a to 132d.

In the variation, since the grooves are not formed in the vicinity of the central portion of the mounting portion 134, a thickness of the joining member 80 between the conductive member 230b and the semiconductor portion 50 can be reduced. Since the joining member 80 may have a lower conductivity and a lower thermal conductivity than those of the conductive member 230b, an increase in a resistance value and heat generation can be prevented by reducing the thickness of the joining member 80. On the other hand, the joining member 80 of a sufficient volume can be formed in the thin portions 132a to 132d via the grooves 236a1 to 236d1.

In this way, it is possible to implement the semiconductor device with a reduced on-resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor portion having a first surface and a second surface located on an opposite side from the first surface, the semiconductor portion including a first region provided between the first surface and the second surface, a second region provided between the first surface and the second surface, and a semiconductor substrate connecting the first region and the second region;
a first electrode provided on the first surface in the first region;
a second electrode provided on the first surface in the second region and spaced apart from the first electrode;
a first control electrode provided in the first region and configured to control a current flowing between the first electrode and the semiconductor substrate;
a second control electrode provided in the second region and configured to control a current flowing between the second electrode and the semiconductor substrate;
a conductive plate having a third surface facing the second surface and a fourth surface located on an opposite side from the third surface, the conductive plate being electrically connected to the semiconductor substrate via the third surface; and
a bonding material having conductivity and provided between the semiconductor substrate and the conductive plate,
the conductive plate including
a mounting portion provided between the third surface and the fourth surface, and
a thin portion having a fifth surface located on an opposite side from the fourth surface and having a thickness between the fifth surface and the fourth surface that is smaller than a thickness of the mounting portion,
the bonding material being provided between the second surface and the third surface and between the second surface and the fifth surface, and
in a plan view,
a shape of an outer periphery of the conductive plate and a shape of an outer periphery of the semiconductor portion being each rectangular,
four first vertices of the conductive plate being disposed corresponding to four second vertices of the semiconductor portion respectively,
the outer periphery of the conductive plate coinciding with the outer periphery of the semiconductor portion or being located outside the outer periphery of the semiconductor portion, and
at least one of the four second vertices being located within a region of the thin portion.

2. The device according to claim 1, wherein
each of the four second vertices is located within the region of the thin portion in the plan view.

3. The device according to claim 2, wherein
the semiconductor portion is disposed such that the outer periphery of the semiconductor portion surrounds a boundary between the thin portion and the mounting portion, and the semiconductor portion is located outside the boundary in the plan view.

4. The device according to claim 2, wherein
a boundary between the thin portion and the mounting portion is rectangular in the plan view.

5. The device according to claim 2, wherein
a boundary between the thin portion and the mounting portion is octagonal in the plan view.

6. The device according to claim 1, wherein
the thin portion has a triangular outer peripheral shape including at least one of the four first vertices in the plan view.

7. The device according to claim 6, wherein
four of the thin portions are provided, and the four thin portions have four triangular outer peripheral shapes respectively including the four first vertices.

8. A semiconductor device comprising:
a semiconductor portion having a first surface and a second surface located on an opposite side from the first surface, the semiconductor portion including a first region provided between the first surface and the second surface, a second region provided between the first surface and the second surface, and a semiconductor substrate connecting the first region and the second region;
a first electrode provided on the first surface in the first region;
a second electrode provided on the first surface in the second region and spaced apart from the first electrode;
a first control electrode provided in the first region and configured to control a current flowing between the first electrode and the semiconductor substrate;
a second control electrode provided in the second region and configured to control a current flowing between the second electrode and the semiconductor substrate;
a conductive plate having a third surface facing the second surface and a fourth surface located on an opposite side from the third surface, the conductive plate being electrically connected to the semiconductor substrate via the third surface; and
a bonding material having conductivity and disposed between the semiconductor substrate and the conductive plate,
the conductive plate including
a mounting portion provided between the third surface and the fourth surface, and
a plurality of thin portions each having a fifth surface located on an opposite side from the fourth surface and each having a thickness between the fifth surface and the fourth surface that is smaller than a thickness of the mounting portion,
the bonding material being provided between the second surface and the third surface, and between the second surface and the fifth surface, and
in a plan view,
outer peripheries of the conductive plate and the semiconductor portion being each rectangular,
four first vertices of the conductive plate being disposed corresponding to four second vertices of the semiconductor portion,
the outer periphery of the conductive plate coinciding with the outer periphery of the semiconductor portion or being located outside the outer periphery of the semiconductor portion, and
the four first vertices being respectively disposed in regions of the plurality of thin portions.

9. The device according to claim 8, wherein
the conductive plate has a groove provided in the third surface,
the groove is provided from the mounting portion to the thin portion, and
the bonding material is provided between the second surface and the third surface, and in the groove.

10. The device according to claim 9, wherein
the conductive plate has a recess provided in the third surface,
the groove is provided from the recess to the thin portion, and
the bonding material is provided between the second surface and the third surface, and in the recess.

11. The device according to claim 8, wherein
the conductive plate has a plurality of grooves provided in the third surface,
the plurality of grooves are separated from one another and disposed toward the four first vertices, and
the bonding material is provided between the second surface and the third surface, and in the plurality of grooves.

12. The device according to claim 1, wherein
the fifth surface includes a concave curved surface.
